(19) United States
(12) Patent Application Publication
(10) Pub. No.: US 2008/0272421 A1
(43) Pub. Date: Nov. 6, 2008

(54) METHODS, CONSTRUCTIONS, AND DEVICES INCLUDING TANTALUM OXIDE LAYERS

(75) Inventor: Vishwanath Bhat, Boise, ID (US)

Correspondence Address: MUETING, RAASCH & GEBHARDT, P.A., P.O. BOX 581336, MINNEAPOLIS, MN, 55458-1336, US

(73) Assignee: MICRON TECHNOLOGY, INC., Boise, ID (US)

(21) Appl. No.: 11/743,246

(22) Filed: May 2, 2007

(51) Int. Cl. H01L 29/94; B05D 5/12; B32B 19/00; H01G 4/008; H01L 21/20

(52) U.S. Cl. 257/310; 361/305; 427/79; 428/698; 438/386; 257/E29.345; 257/E21.09

(57) ABSTRACT

Methods, constructions, and devices that include tantalum oxide layers adjacent to niobium nitride are disclosed herein. In certain embodiments, the niobium nitride is crystalline and has a hexagonal close-packed structure. Optionally, the niobium nitride can have a surface that includes niobium oxide adjacent to at least a portion thereof. In certain embodiments, the tantalum oxide layer is crystallographically textured and has a hexagonal structure.

### BACKGROUND

The scaling down of integrated circuit devices has created a need to incorporate high dielectric constant (i.e., high dielectric permittivity) materials into capacitors and gates. The search for new high dielectric constant materials and processes is becoming more important as the minimum size for current technology is practically constrained by the use of standard dielectric materials.

Tantalum oxide (e.g., Ta₂O₅) has found interest as a high dielectric permittivity material for applications such as DRAM capacitors because of its high dielectric constant (e.g., 30) and low leakage currents. Even further interest has been directed to crystalline tantalum oxide for such applications, because thin films of crystalline tantalum oxide have dielectric constants of 60, which is about twice the dielectric constant of thin films of amorphous tantalum oxide. For example, tantalum oxide has been deposited on metallic ruthenium having a hexagonal close-packed structure to form a crystallographically textured tantalum oxide layer. However, because a ruthenium surface can be easily oxidized, and the oxidized surface can inhibit the formation of crystalline Ta₂O₅, extra measures are typically required to control the nature and composition of the ruthenium surface before and/or during the deposition process.

New methods of preparing high dielectric constant films are being sought for current and new generations of integrated circuit devices.

### BRIEF DESCRIPTION OF THE DRAWING

FIG. 1 is a schematic side view illustrating an embodiment of a construction having a tantalum oxide layer adjacent to niobium nitride as further described in the present disclosure.

FIG. 2 is an example capacitor construction having a tantalum oxide dielectric layer adjacent to at least a portion of a niobium nitride electrode as further described in the present disclosure.

The following description of various embodiments of the methods as described herein is not intended to describe each embodiment or every implementation of such methods. Rather, a more complete understanding of the methods as described herein will become apparent and appreciated by reference to the following description and claims in view of the accompanying drawing. Further, it is to be understood that other embodiments may be utilized and structural changes may be made without departing from the scope of the present disclosure.

### DETAILED DESCRIPTION OF ILLUSTRATIVE EMBODIMENTS

A tantalum oxide layer adjacent to a niobium nitride (e.g., NbN) surface can be crystallographically textured (e.g., c-axis textured). In certain embodiments, at least a portion of the niobium nitride surface is crystalline (e.g., polycrystalline) and has a hexagonal close-packed structure. For example, a tantalum oxide layer can be deposited adjacent to a niobium nitride surface having a hexagonal close-packed structure to form a crystalline tantalum oxide layer, as deposited and/or after annealing. In certain embodiments, the tantalum oxide layer has a hexagonal structure (e.g., an orthorhombic-hexagonal phase). In certain embodiments, the tantalum oxide layer has a dielectric constant of at least 50. Such niobium nitride/tantalum oxide constructions can be useful as portions of, or intermediates for making, capacitors (e.g., DRAM applications), in which an electrode includes niobium nitride and the tantalum oxide forms a dielectric layer. As used herein, the term “or” is generally employed in the sense as including “and/or” unless the context of the usage clearly indicates otherwise. Optionally, a second electrode can be adjacent to the dielectric layer. The second electrode can include a wide variety of materials known for use as electrodes. For example, such materials can include, but are not limited to, ruthenium, niobium nitride, tantalum nitride, hafnium nitride, and combinations thereof.

In some embodiments, oxidation of at least a portion of the niobium nitride surface can occur before, during, and/or after depositing the tantalum oxide, to form niobium oxide (e.g., Nb₂O₅) adjacent to at least a portion of the surface. In contrast to oxidation of a ruthenium surface, which can lead to difficulties in texturing the tantalum oxide layer, the optional formation of niobium oxide (e.g., amorphous, partially crystalline, or crystalline) adjacent to at least a portion of the niobium nitride surface can actually be advantageous, for example, by decreasing the temperature required to crystallize the tantalum oxide layer. Specifically, the crystallization temperature of a tantalum oxide/niobium oxide bilayer has been reported to be 100° C. lower than the crystallization temperature of a tantalum oxide single layer (see, for example, Cho et al., Microelectronic Engineering, 80 (2005) 317-320).

The following examples are offered to further illustrate various specific embodiments and techniques of the present disclosure. It should be understood, however, that many variations and modifications understood by those of ordinary skill in the art may be made while remaining within the scope of the present disclosure. Therefore, the scope of the present disclosure is not intended to be limited by the following example.

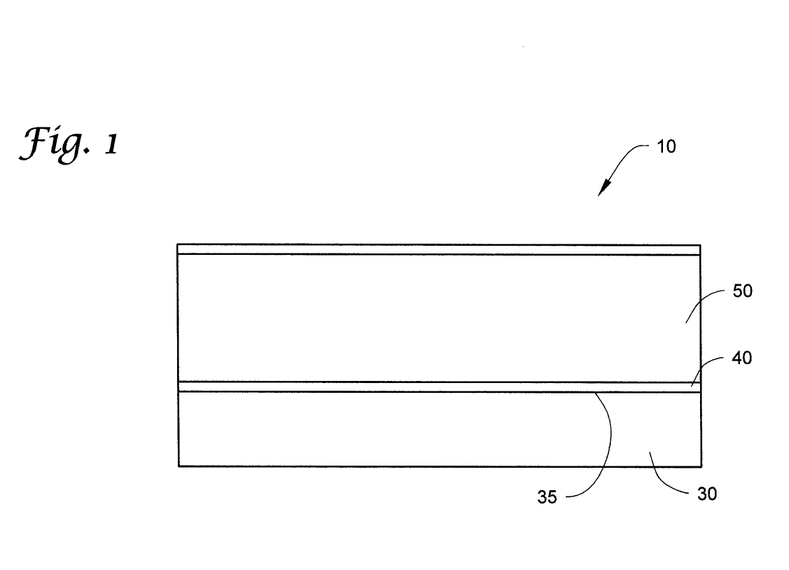

An example niobium nitride/tantalum oxide construction is illustrated in FIG. 1. Niobium nitride/tantalum oxide construction 10 includes tantalum oxide layer 50 adjacent to at least a portion of niobium nitride 30. Niobium nitride 30 can have any suitable thickness. In some embodiments, niobium nitride 30 has a thickness of from 100 Å to 300 Å. In some embodiments, at least the surface of niobium nitride 30 is polycrystalline and has a hexagonal close-packed structure. Optionally, construction 10 can include niobium oxide 40 adjacent to at least a portion of surface 35 of niobium nitride 30. “Layer,” as used herein, is meant to include layers specific to the semiconductor industry, such as, but clearly not limited to, a barrier layer, dielectric layer (i.e., a layer having a high dielectric constant), and conductive layer. The term “layer” is synonymous with the term “film” frequently used in the semiconductor industry. The term “layer” is also meant to include layers found in technology outside of semiconductor technology, such as coatings on glass. For example, such layers can be formed directly on fibers, wires, etc., which are substrates other than semiconductor substrates. Further, the layers can be formed adjacent to (e.g., directly on) the lowest semiconductor surface of the substrate, or they can be formed adjacent to any of a variety of layers (e.g., surfaces) as in, for example, a patterned wafer. As used herein, layers need not be continuous, and in certain embodiments are discontinuous. Unless otherwise stated, as used herein, a layer or material “adjacent to” or “on” a surface (or another layer) is intended to be broadly interpreted to include not only constructions having a layer or material directly on the surface, but also constructions in which the surface and the layer or material are separated by one or more additional materials (e.g., layers).

Niobium nitride 30 can be deposited, for example, adjacent to a substrate, (e.g., a semiconductor substrate or substrate assembly), which is not illustrated in FIG. 1. “Semiconductor substrate” or “substrate assembly” as used herein refer to a semiconductor substrate such as a base semiconductor material or a semiconductor substrate having one or more materials, structures, or regions formed thereon. A base semiconductor material is typically the lowest silicon material on a wafer or a silicon material deposited adjacent to another material, such as silicon on sapphire. When reference is made to a substrate assembly, various process steps may have been previously used to form or define regions, junctions, various structures or features, and openings such as transistors, active areas, diffusions, implanted regions, vias, contact openings, high aspect ratio openings, capacitor plates, barriers for capacitors, etc.

Suitable substrate materials of the present disclosure include conductive materials, semiconductive materials, conductive metal-nitrides, conductive metals, conductive metal oxides, etc. The substrate can be a semiconductor substrate or substrate assembly. A wide variety of semiconductor materials are contemplated, such as for example, borophosphosilicate glass (BPSG), silicon such as, e.g., conductively doped polysilicon, monocrystalline silicon, etc. (for this disclosure, appropriate forms of silicon are simply referred to as “silicon”), for example in the form of a silicon wafer, tetraethylorthosilicate (TEOS) oxide, spin on glass (i.e., SiO₂, optionally doped, deposited by a spin on process), TiN, TaN, W, Ru, Al, Cu, noble metals, etc. A substrate assembly may also include a portion that includes platinum, iridium, iridium oxide, rhodium, ruthenium, ruthenium oxide, strontium ruthenate, lanthanum nickelate, titanium nitride, tantalum nitride, tantalum-silicon-nitride, silicon dioxide, aluminum, gallium arsenide, glass, etc., and other existing or to-be-developed materials used in semiconductor constructions, such as dynamic random access memory (DRAM) devices, static random access memory (SRAM) devices, and ferroelectric memory (FERAM) devices, for example.

For substrates including semiconductor substrates or substrate assemblies, materials can be formed adjacent to or directly on the lowest semiconductor surface of the substrate, or they can be formed adjacent to any of a variety of other surfaces as in a patterned wafer, for example.

Substrates other than semiconductor substrates or substrate assemblies can also be used in presently disclosed methods. Any substrate that may advantageously form niobium nitride thereon may be used, such substrates including, for example, fibers, wires, etc.

Metal-containing materials (e.g., niobium nitride-containing materials and/or tantalum oxide-containing materials) as described herein can be formed by a wide variety of deposition methods including, for example, evaporation, physical vapor deposition (PVD or sputtering), and/or vapor deposition methods such as chemical vapor deposition (CVD) or atomic layer deposition (ALD).

Metal-containing precursor compositions can be used to form metal-containing materials (e.g., niobium nitride-containing materials and/or tantalum oxide-containing materials) in various embodiments described in the present disclosure. As used herein, “metal-containing” is used to refer to a material, typically a compound or a layer, that may consist entirely of a metal, or may include other elements in addition to a metal. Typical metal-containing compounds include, but are not limited to, metals, metal-ligand complexes, metal salts, organometallic compounds, and combinations thereof. Typical metal-containing layers include, but are not limited to, metals, metal oxides, metal nitrides, and combinations thereof.

Various metal-containing compounds can be used in various combinations, optionally with one or more organic solvents (particularly for CVD processes), to form a precursor composition. Some of the metal-containing compounds disclosed herein can be used in ALD without adding solvents. “Precursor” and “precursor composition” as used herein, refer to a composition usable for forming, either alone or with other precursor compositions (or reactants), a material adjacent to a substrate assembly in a deposition process. Further, one skilled in the art will recognize that the type and amount of precursor used will depend on the content of a material which is ultimately to be formed using a vapor deposition process. In certain embodiments of the methods as described herein, the precursor compositions are liquid at the vaporization temperature, and sometimes liquid at room temperature.

The precursor compositions may be liquids or solids at room temperature, and for certain embodiments are liquids at the vaporization temperature. Typically, they are liquids sufficiently volatile to be employed using known vapor deposition techniques. However, as solids they may also be sufficiently volatile that they can be vaporized or sublimed from the solid state using known vapor deposition techniques. If they are less volatile solids, they can be sufficiently soluble in an organic solvent or have melting points below their decomposition temperatures such that they can be used, for example, in flash vaporization, bubbling, microdroplet formation techniques, etc.

Herein, vaporized metal-containing compounds may be used either alone or optionally with vaporized molecules of other metal-containing compounds or optionally with vaporized solvent molecules or inert gas molecules, if used. As used herein, “liquid” refers to a solution or a neat liquid (a liquid at room temperature or a solid at room temperature that melts at an elevated temperature). As used herein, “solution” does not require complete solubility of the solid but may allow for some undissolved solid, as long as there is a sufficient amount of the solid delivered by the organic solvent into the vapor phase for chemical vapor deposition processing. If solvent dilution is used in deposition, the total molar concentration of solvent vapor generated may also be considered as an inert carrier gas.

“Inert gas” or “non-reactive gas,” as used herein, is any gas that is generally unreactive with the components it comes in contact with. For example, inert gases are typically selected from a group including nitrogen, argon, helium, neon, krypton, xenon, any other non-reactive gas, and mixtures thereof. Such inert gases are generally used in one or more purging processes as described herein, and in some embodiments may also be used to assist in precursor vapor transport.

Solvents that are suitable for certain embodiments of methods as described herein may be one or more of the following: aliphatic hydrocarbons or unsaturated hydrocarbons (C3-C20, and in certain embodiments C5-C10, cyclic, branched, or linear), aromatic hydrocarbons (C5-C20, and in certain embodiments C5-C10), halogenated hydrocarbons, silylated hydrocarbons such as alkylsilanes, alkylsilicates, ethers, cyclic ethers (e.g., tetrahydrofuran, THF), polyethers, thioethers, esters, lactones, nitrites, silicone oils, or compounds containing combinations of any of the above or mixtures of one or more of the above. The compounds are also generally compatible with each other, so that mixtures of variable quantities of the metal-containing compounds will not interact to significantly change their physical properties.

Methods as described herein use metal precursor compounds. As used herein, a “metal precursor compound” is used to refer to a compound that can provide a source of the metal in an atomic layer deposition method. Further, in some embodiments, the methods include “metal-organic” precursor compounds. The term “metal-organic” is intended to be broadly interpreted as referring to a compound that includes in addition to a metal, an organic group (i.e., a carbon-containing group). Thus, the term “metal-organic” includes, but is not limited to, organometallic compounds, metal-ligand complexes, metal salts, and combinations thereof.

Niobium-containing materials can be formed from a wide variety of niobium-containing precursor compounds using vapor deposition methods. Niobium-containing precursor compounds known in the art include, for example, Nb(OMe)₅; Nb(OEt)₅; Nb(OBu)₅; NbX₅ wherein each X is a halide (e.g., fluoride, chloride, and/or iodide); Nb(OEt)₄(Me₂NCH₂CH₂O) (also known as niobium tetraethoxy dimethylaminoethoxide or NbTDMAE); Nb(OEt)₄(MeOCH₂CH₂O); other niobium-containing precursor compounds as described in U.S. Patent Application Publication No. 2006/0040480 A1 (Derderian et al.); and combinations thereof, wherein Me is methyl, Et is ethyl, and Bu is butyl.

In certain embodiments, niobium nitride can be formed by a vapor deposition method using niobium-containing precursor compounds and a nitrogen source or a nitrogen-containing precursor compound such as an organic amine as described, for example, in U.S. Pat. No. 6,967,159 B2 (Vaartstra) and/or a disilazane as described, for example, in U.S. Pat. No. 7,196,007 B2 (Vaartstra).

In certain embodiments, at least a portion of the niobium nitride is crystalline and has a hexagonal close-packed structure. In certain embodiments, the niobium nitride material can have a thickness of from 100 Å to 300 Å, although the thickness can be selected as desired from within or outside this range depending on the particular application. As used herein, the recitations of numerical ranges by endpoints include all numbers subsumed within that range (e.g., 1 to 5 includes 1, 1.5, 2, 2.75, 3, 3.80, 4, 5, etc.).

Tantalum oxide-containing layers can be formed from a wide variety of tantalum-containing precursor compounds using vapor deposition methods. Tantalum-containing precursor compounds known in the art include, for example, Ta(OMe)₅; Ta(OEt)₅; Ta(OBu)₅; TaX₅ wherein each X is a halide (e.g., fluoride, chloride, and/or iodide); pentakis(dimethylamino)tantalum, tris(diethylamino)(ethylimino)tantalum, and tris(diethylamino)(tert-butylimino)tantalum; other tantalum-containing precursor compounds as described in U.S. Pat. No. 7,030,042 B2 (Vaartstra et al.); and combinations thereof, wherein Me is methyl, Et is ethyl, and Bu is butyl. In certain embodiments, the tantalum oxide layer is deposited at a deposition temperature of from 300° C. to 450° C.

In certain embodiments, a tantalum oxide-containing layer can be formed by a vapor deposition method using tantalum oxide-containing precursor compounds and optionally a reaction gas (e.g., water vapor) as described, for example, in U.S. Pat. No. 7,030,042 B2 (Vaartstra et al.).

In certain embodiments, the tantalum oxide layer has a hexagonal structure (e.g., an orthorhombic-hexagonal phase). In certain embodiments, the tantalum oxide layer has a dielectric constant of from 40 to 110. In other certain embodiments, the tantalum oxide layer has a dielectric constant of at least 50. In certain embodiments, the tantalum oxide layer can have a thickness of from 60 Å to 200 Å, although the thickness can be selected as desired from within or outside this range depending on the particular application.

Precursor compositions as described herein can, optionally, be vaporized and deposited/chemisorbed substantially simultaneously with, and in the presence of, one or more reaction gases. Alternatively, metal-containing materials may be formed by alternately introducing the precursor composition and the reaction gas(es) during each deposition cycle. Such reaction gases can include, for example, nitrogen-containing sources (e.g., ammonia) and oxygen-containing sources, which can be oxidizing gases. A wide variety of suitable oxidizing gases can be used including, for example, air, oxygen, water vapor, ozone, nitrogen oxides (e.g., nitric oxide), hydrogen peroxide, alcohols (e.g., isopropanol), and combinations thereof.

The precursor compositions can be vaporized in the presence of an inert carrier gas if desired. Additionally, an inert carrier gas can be used in purging steps in an ALD process (discussed below). The inert carrier gas is typically one or more of nitrogen, helium, argon, etc. In the context of the present disclosure, an inert carrier gas is one that does not interfere with the formation of the metal-containing material. Whether done in the presence of a inert carrier gas or not, the vaporization can be done in the absence of oxygen to avoid oxygen contamination (e.g., oxidation of silicon to form silicon dioxide or oxidation of precursor in the vapor phase prior to entry into the deposition chamber).

The terms “deposition process” and “vapor deposition process” as used herein refer to a process in which a metal-containing material is formed adjacent to one or more surfaces of a substrate (e.g., a doped polysilicon wafer) from vaporized precursor composition(s) including one or more metal-containing compound(s). Specifically, one or more metal-containing compounds are vaporized and directed to and/or contacted with one or more surfaces of a substrate (e.g., semiconductor substrate or substrate assembly) placed in a deposition chamber. Typically, the substrate is heated. These metal-containing compounds can form (e.g., by reacting or decomposing) a non-volatile, thin, uniform, metal-containing material adjacent to the surface(s) of the substrate. For the purposes of this disclosure, the term “vapor deposition process” is meant to include both chemical vapor deposition processes (including pulsed chemical vapor deposition processes) and atomic layer deposition processes.

Chemical vapor deposition (CVD) and atomic layer deposition (ALD) are two vapor deposition processes often employed to form thin, continuous, uniform, metal-containing materials onto semiconductor substrates. Using either vapor deposition process, typically one or more precursor compositions are vaporized in a deposition chamber and optionally combined with one or more reaction gases and directed to and/or contacted with the substrate to form a metal-containing material on the substrate. It will be readily apparent to one skilled in the art that the vapor deposition process may be enhanced by employing various related techniques such as plasma assistance, photo assistance, laser assistance, as well as other techniques.

A typical CVD process may be carried out in a chemical vapor deposition reactor, such as a deposition chamber available under the trade designation of 7000 from Genus, Inc. (Sunnyvale, Calif.), a deposition chamber available under the trade designation of 5000 from Applied Materials, Inc. (Santa Clara, Calif.), or a deposition chamber available under the trade designation of Prism from Novelus, Inc. (San Jose, Calif.). However, any deposition chamber suitable for performing CVD may be used.

The term “atomic layer deposition” (ALD) as used herein refers to a vapor deposition process in which deposition cycles, for example a plurality of consecutive deposition cycles, are conducted in a process chamber (i.e., a deposition chamber). As used herein, a “plurality” means two or more. Typically, during each cycle a precursor is chemisorbed to a deposition surface (e.g., a substrate assembly surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition,” “atomic layer epitaxy” (ALE) (see U.S. Pat. No. 5,256,244 to Ackerman), molecular beam epitaxy (MBE), gas source MBE, or organometallic MBE, and chemical beam epitaxy when performed with alternating pulses of precursor composition(s), reactive gas, and purge (e.g., inert carrier) gas.

The vapor deposition process employed in the methods of the present disclosure can be a multi-cycle atomic layer deposition (ALD) process. Such a process is advantageous, in particular advantageous over a CVD process, in that it provides for improved control of atomic-level thickness and uniformity to the deposited material (e.g., dielectric layer) by providing a plurality of self-limiting deposition cycles. The self-limiting nature of ALD provides a method of depositing a film adjacent to a wide variety of reactive surfaces including, for example, surfaces with irregular topographies, with better step coverage than is available with CVD or other “line of sight” deposition methods (e.g., evaporation and physical vapor deposition, i.e., PVD or sputtering). Further, ALD processes typically expose the metal-containing compounds to lower volatilization and reaction temperatures, which tends to decrease degradation of the precursor as compared to, for example, typical CVD processes.

Generally, in an ALD process each reactant is pulsed onto a suitable substrate, typically at deposition temperatures of at least 25° C., in certain embodiments at least 150° C., and in other embodiments at least 200° C. Typical ALD deposition temperatures are no greater than 400° C., in certain embodiments no greater than 350° C., and in other embodiments no greater than 250° C. These temperatures are generally lower than those presently used in CVD processes, which typically include deposition temperatures at the substrate surface of at least 150° C., in some embodiments at least 200° C., and in other embodiments at least 250° C. Typical CVD deposition temperatures are no greater than 600° C., in certain embodiments no greater than 500° C., and in other embodiments no greater than 400° C.

Under such conditions the film growth by ALD is typically self-limiting (i.e., when the reactive sites on a surface are depleted in an ALD process, the deposition generally stops), which can provide for substantial deposition conformity within a wafer and deposition thickness control. Due to alternate dosing of the precursor compositions and/or reaction gases, detrimental vapor-phase reactions are inherently diminished, in contrast to the CVD process that is carried out by continuous co-reaction of the precursors and/or reaction gases. (See Vehkamäki et al, “Growth of SrTiO₃ and BaTiO₃ Thin Films by Atomic Layer Deposition,” Electrochemical and Solid-State Letters, 2(10):504-506 (1999)).

A typical ALD process includes exposing a substrate (which may optionally be pretreated with, for example, water and/or ozone) to a first chemical to accomplish chemisorption of the chemical onto the substrate. The term “chemisorption” as used herein refers to the chemical adsorption of vaporized reactive metal-containing compounds on the surface of a substrate. The adsorbed chemicals are typically irreversibly bound to the substrate surface as a result of relatively strong binding forces characterized by high adsorption energies (e.g., >30 kcal/mol), comparable in strength to ordinary chemical bonds. The chemisorbed chemicals typically form a monolayer on the substrate surface. (See “The Condensed Chemical Dictionary,” 10th edition, revised by G. G. Hawley, published by Van Nostrand Reinhold Co., New York, 225 (1981)). In ALD one or more appropriate precursor compositions or reaction gases are alternately introduced (e.g., pulsed) into a deposition chamber and chemisorbed onto the surfaces of a substrate. Each sequential introduction of a reactive compound (e.g., one or more precursor compositions and one or more reaction gases) is typically separated by an inert carrier gas purge to provide for deposition and/or chemisorption of a second reactive compound in the substantial absence of the first reactive compound. As used herein, the “substantial absence” of the first reactive compound during deposition and/or chemisorption of the second reactive compound means that no more than insignificant amounts of the first reactive compound might be present. According to the knowledge of one of ordinary skill in the art, a determination can be made as to the tolerable amount of the first reactive compound, and process conditions can be selected to achieve the substantial absence of the first reactive compound.

Each precursor composition co-reaction adds a new atomic layer to previously deposited layers to form a cumulative solid. The cycle is repeated to gradually form the desired thickness. It should be understood that ALD can alternately utilize one precursor composition, which is chemisorbed, and one reaction gas, which reacts with the chemisorbed precursor composition.

Practically, chemisorption might not occur on all portions of the deposition surface (e.g., previously deposited ALD material). Nevertheless, such imperfect monolayer is still considered a monolayer in the context of the present disclosure. In many applications, merely a substantially saturated monolayer may be suitable. In one aspect, a substantially saturated monolayer is one that will still yield a deposited monolayer or less of material exhibiting the desired quality and/or properties. In another aspect, a substantially saturated monolayer is one that is self-limited to further reaction with precursor.

A typical ALD process includes exposing an initial substrate to a first chemical A (e.g., a precursor composition such as a metal-containing compound as described herein or a reaction gas), to accomplish chemisorption of chemical A onto the substrate. Chemical A can react either with the substrate surface or with chemical B (described below), but not with itself. When chemical A is a metal-containing compound having ligands, one or more of the ligands is typically displaced by reactive groups on the substrate surface during chemisorption. Theoretically, the chemisorption forms a monolayer that is uniformly one atom or molecule thick on the entire exposed initial substrate, the monolayer being composed of chemical A, less any displaced ligands. In other words, a saturated monolayer is substantially formed on the substrate surface.

Substantially all non-chemisorbed molecules of chemical A as well as displaced ligands are purged from over the substrate and a second chemical, chemical B (e.g., a different metal-containing compound or reaction gas) is provided to react with the monolayer of chemical A. Chemical B typically displaces the remaining ligands from the chemical A monolayer and thereby is chemisorbed and forms a second monolayer. This second monolayer displays a surface which is reactive only to chemical A. Non-chemisorbed chemical B, as well as displaced ligands and other byproducts of the reaction are then purged and the steps are repeated with exposure of the chemical B monolayer to vaporized chemical A. Optionally, chemical B can react with chemical A, but not chemisorb additional material thereto. That is, chemical B can cleave some portion of the chemisorbed chemical A, altering such monolayer without forming another monolayer thereon, but leaving reactive sites available for formation of subsequent monolayers. In other ALD processes, a third or more chemicals may be successively chemisorbed (or reacted) and purged just as described for chemical A and chemical B, with the understanding that each introduced chemical reacts with the monolayer produced immediately prior to its introduction. Optionally, chemical B (or third or subsequent chemicals) can include at least one reaction gas if desired.

Thus, the use of ALD provides the ability to improve the control of thickness, composition, and uniformity of metal-containing materials adjacent to a substrate. For example, depositing thin layers of metal-containing compound in a plurality of cycles provides a more accurate control of ultimate film thickness. This is particularly advantageous when precursor composition(s) are directed to the substrate and allowed to chemisorb thereon, optionally further including at least one reaction gas that can react with the chemisorbed precursor composition(s) on the substrate, and in certain embodiments wherein this cycle is repeated at least once.

Purging of excess vapor of each chemical following deposition and/or chemisorption onto a substrate may involve a variety of techniques including, but not limited to, contacting the substrate and/or monolayer with an inert carrier gas and/or lowering pressure to below the deposition pressure to reduce the concentration of a chemical contacting the substrate and/or chemisorbed chemical. Examples of carrier gases, as discussed above, may include N₂, Ar, He, etc. Additionally, purging may instead include contacting the substrate and/or monolayer with any substance that allows chemisorption by-products to desorb and reduces the concentration of a contacting chemicals preparatory to introducing another chemical. The contacting chemical may be reduced to some suitable concentration or partial pressure known to those skilled in the art based on the specifications for the product of a particular deposition process.

ALD is often described as a self-limiting process, in that a finite number of sites exist on a substrate to which the first chemical may form chemical bonds. The second chemical might only react with the surface created from the chemisorption of the first chemical and thus, may also be self-limiting. Once all of the finite number of sites on a substrate are bonded with a first chemical, the first chemical will not bond to other of the first chemicals already bonded with the substrate. However, process conditions can be varied in ALD to promote such bonding and render ALD not self-limiting, e.g., more like pulsed CVD. Accordingly, ALD may also encompass chemicals forming other than one monolayer at a time by stacking of chemicals, forming a material more than one atom or molecule thick.

Thus, during the ALD process, numerous consecutive deposition cycles can be conducted in the deposition chamber, each cycle depositing a very thin metal-containing layer (usually less than one monolayer such that the growth rate on average is 0.02 to 0.3 nanometers per cycle), until material of the desired thickness is built up adjacent to the substrate of interest. The deposition can be accomplished by alternately introducing (i.e., by pulsing) precursor composition(s) into the deposition chamber containing a substrate, chemisorbing the precursor composition(s) as a monolayer onto the substrate surfaces, purging the deposition chamber, then introducing to the chemisorbed precursor composition(s) reaction gases and/or other precursor composition(s) in a plurality of deposition cycles until the desired thickness of the metal-containing material is achieved.

The pulse duration of precursor composition(s) and inert carrier gas(es) is generally of a duration sufficient to saturate the substrate surface. Typically, the pulse duration is at least 0.1 seconds, in certain embodiments at least 0.2 second, and in other embodiments at least 0.5 second. Typically pulse durations are generally no greater than 2 minutes, and in certain embodiments no greater than 1 minute.

In comparison to the predominantly thermally driven CVD, ALD is predominantly chemically driven. Thus, ALD may advantageously be conducted at much lower temperatures than CVD. During the ALD process, the substrate temperature may be maintained at a temperature sufficiently low to maintain intact bonds between the chemisorbed chemical(s) and the underlying substrate surface and to prevent decomposition of the chemical(s) (e.g., precursor compositions). The temperature, on the other hand, must be sufficiently high to avoid condensation of the chemical(s) (e.g., precursor compositions). Typically the substrate is kept at a temperature of at least 25° C., in certain embodiments at least 150° C., and in other certain embodiments at least 200° C. Typically the substrate is kept at a temperature of no greater than 400° C., in certain embodiments no greater than 350° C., and in other certain embodiments no greater than 300° C., which, as discussed above, is generally lower than temperatures presently used in typical CVD processes. The first chemical or precursor composition can be chemisorbed at a first temperature, and the surface reaction of the second chemical or precursor composition can occur at substantially the same temperature or, optionally, at a substantially different temperature. Clearly, some small variation in temperature, as judged by those of ordinary skill, can occur but still be considered substantially the same temperature by providing a reaction rate statistically the same as would occur at the temperature of the first chemical or precursor chemisorption. Alternatively, chemisorption and subsequent reactions could instead occur at substantially exactly the same temperature.

For a typical vapor deposition process, the pressure inside the deposition chamber can be at least 10⁻⁸ torr (1.3×10⁻⁶ Pascal, “Pa”), in certain embodiments at least 10⁻⁷ torr (1.3×10⁻⁵ Pa), and in other certain embodiments at least 10⁻⁶ torr (1.3×10⁻⁴ Pa). Further, deposition pressures are typically no greater than 10 torr (1.3×10³ Pa), in certain embodiments no greater than 5 torr (6.7×10² Pa), and in other certain embodiments no greater than 2 torr (2.7×10² Pa). Typically, the deposition chamber is purged with an inert carrier gas after the vaporized precursor composition(s) have been introduced into the chamber and/or reacted for each cycle. The inert carrier gas/gases can also be introduced with the vaporized precursor composition(s) during each cycle.

The reactivity of a precursor composition can significantly influence the process parameters in ALD. Under typical CVD process conditions, a highly reactive chemical (e.g., a highly reactive precursor composition) may react in the gas phase generating particulates, depositing prematurely on undesired surfaces, producing inadequate films, and/or inadequate step coverage or otherwise yielding non-uniform deposition. For at least such reason, a highly reactive chemical might be considered not suitable for CVD. However, some chemicals not suitable for CVD are superior in precursor compositions for ALD. For example, if the first chemical is gas phase reactive with the second chemical, such a combination of chemicals might not be suitable for CVD, although they could be used in ALD. In the CVD context, concern might also exist regarding sticking coefficients and surface mobility, as known to those skilled in the art, when using highly gas-phase reactive chemicals, however, little or no such concern would exist in the ALD context.

A tantalum oxide layer adjacent to at least a portion of a niobium nitride (e.g., NbN) surface can be crystallographically textured (e.g., c-axis textured). For example, a tantalum oxide layer can be deposited adjacent to or directly on a niobium nitride surface having a hexagonal close-packed structure to form a crystalline tantalum oxide layer, as deposited and/or after annealing. In certain embodiments, the tantalum oxide layer has a hexagonal structure (e.g., an orthorhombic-hexagonal phase). In certain embodiments, the tantalum oxide layer has a dielectric constant of at least 50.

After formation of tantalum oxide adjacent to the substrate, an annealing process may be optionally performed in situ in the deposition chamber in a reducing, inert, plasma, or oxidizing atmosphere. Typically the annealing temperature can be at least 400° C., in some embodiments at least 500° C., and in some other embodiments at least 600° C. The annealing temperature is typically no greater than 1000° C., in some embodiments no greater than 750° C., and in some other embodiments no greater than 700° C.

The annealing operation is typically performed for a time period of at least 0.5 minute, and in certain embodiments for a time period of at least 1 minute. Additionally, the annealing operation is typically performed for a time period of no greater than 60 minutes, and in certain embodiments for a time period of no greater than 10 minutes. In certain embodiments, annealing includes a rapid thermal annealing method at a temperature of from 500° C. to 600° C. for a time period of from 30 seconds to 3 minutes. In other certain embodiments, annealing includes annealing in a furnace at a temperature of from 500° C. to 600° C. for a time period of from 15 minutes to 2 hours.

One skilled in the art will recognize that such temperatures and time periods may vary. For example, furnace anneals and rapid thermal annealing may be used, and further, such anneals may be performed in one or more annealing steps.

As stated above, the use of the compounds and methods of forming films of the present disclosure are beneficial for a wide variety of thin film applications in semiconductor structures, particularly those using high dielectric permittivity materials. For example, such applications include gate dielectrics and capacitors such as planar cells, trench cells (e.g., double sidewall trench capacitors), stacked cells (e.g., crown, V-cell, delta cell, multi-fingered, or cylindrical container stacked capacitors), as well as field effect transistor devices.

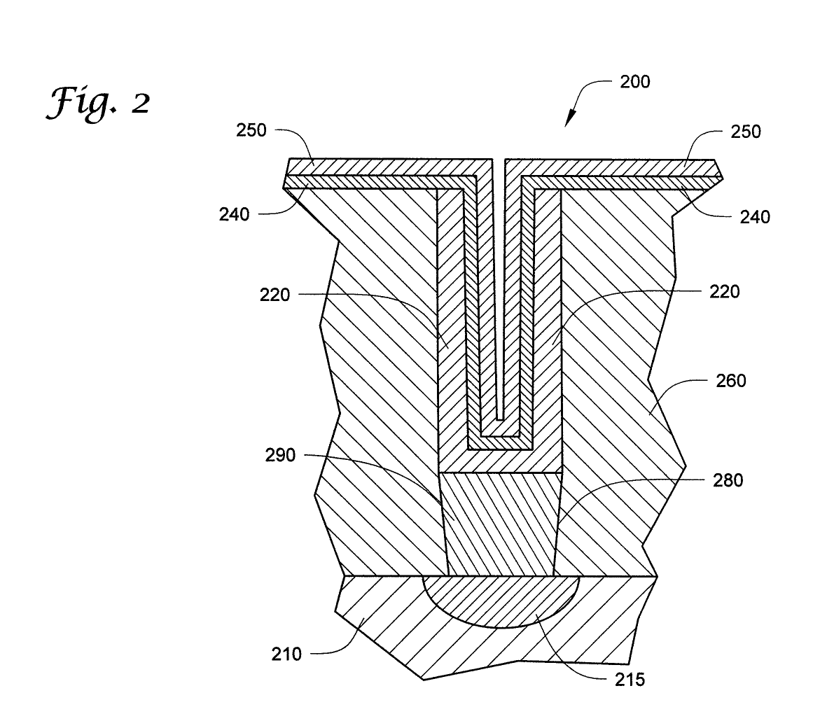

FIG. 2 shows an example of the ALD formation of metal-containing layers of the present disclosure as used in an example capacitor construction. Referring to FIG. 2, capacitor construction 200 includes substrate 210 having conductive diffusion area 215 formed therein. Substrate 210 can include, for example, silicon. An insulating material 260, such as BPSG, is provided over substrate 210, with contact opening 280 provided therein to diffusion area 215. Conductive material 290 fills contact opening 280, and may include, for example, tungsten or conductively doped polysilicon. Capacitor construction 200 includes a first capacitor niobium nitride electrode (a bottom electrode) 220, a tantalum oxide dielectric layer 240 which may be formed by methods as described herein, and a second capacitor electrode (a top electrode) 250.

It is to be understood that FIG. 2 is an example construction, and methods as described herein can be useful for forming materials adjacent to any substrate, for example semiconductor structures, and that such applications include, but are not limited to, capacitors such as planar cells, trench cells, (e.g., double sidewall trench capacitors), stacked cells (e.g., crown, V-cell, delta cell, multi-fingered, or cylindrical container stacked capacitors), as well as field effect transistor devices.

Furthermore, a diffusion barrier material may optionally be formed over the tantalum oxide dielectric layer 240, and may, for example, include TiN, TaN, metal silicide, or metal silicide-nitride. While the diffusion barrier material is described as a distinct material, it is to be understood that the barrier materials may include conductive materials and can accordingly, in such embodiments, be understood to include at least a portion of the capacitor electrodes. In certain embodiments that include a diffusion barrier material, an entirety of a capacitor electrode can include conductive barrier materials.

The complete disclosures of the patents, patent documents, and publications cited herein are incorporated by reference in their entirety as if each were individually incorporated. Various modifications and alterations to the embodiments described herein will become apparent to those skilled in the art without departing from the scope and spirit of the present disclosure. It should be understood that this disclosure is not intended to be unduly limited by the illustrative embodiments and examples set forth herein and that such examples and embodiments are presented by way of example only with the scope of the disclosure intended to be limited only by the claims set forth herein as follows. As used herein, the term “comprising,” which is synonymous with “including” or “containing,” is inclusive, open-ended, and does not exclude additional unrecited elements or method steps.

What is claimed is:

1. A construction comprising:
an electrode comprising niobium nitride; and
a tantalum oxide layer adjacent to at least a portion of the electrode.

2. The construction of claim 1 wherein the electrode comprises a niobium nitride surface.

3. The construction of claim 1 wherein the electrode comprises a surface having niobium oxide adjacent to at least a portion thereof.

4. The construction of claim 3 wherein at least a portion of the niobium oxide is amorphous.

5. The construction of claim 3 wherein at least a portion of the niobium oxide is crystalline.

6. The construction of claim 3 wherein the tantalum oxide layer is adjacent to at least a portion of the electrode having niobium oxide thereon.

7. A construction comprising:
an electrode comprising crystalline niobium nitride having a hexagonal close-packed structure; and
a tantalum oxide layer adjacent to at least a portion of the electrode.

8. The construction of claim 7 wherein at least a portion of the tantalum oxide layer is crystalline.

9. The construction of claim 8 wherein at least a portion of the crystalline tantalum oxide has a hexagonal structure.

10. The construction of claim 8 wherein at least a portion of the crystalline tantalum oxide is crystallographically textured.

11. The construction of claim 10 wherein the crystallographically textured tantalum oxide is c-axis textured.

12. The construction of claim 11 wherein the c-axis textured tantalum oxide has a hexagonal structure.

13. The construction of claim 7 wherein the tantalum oxide layer has a dielectric constant of at least 50.

14. A capacitor comprising:
a first electrode comprising niobium nitride;
a tantalum oxide layer adjacent to at least a portion of the first electrode; and
a second electrode adjacent to at least a portion of the tantalum oxide layer.

15. The capacitor of claim 14 wherein the second electrode comprises niobium nitride and/or ruthenium.

16. A capacitor comprising:
a first electrode comprising crystalline niobium nitride having a hexagonal close-packed structure;
a tantalum oxide layer adjacent to at least a portion of the first electrode; and
a second electrode adjacent to at least a portion of the tantalum oxide layer.

17. The capacitor of claim 16 wherein the tantalum oxide layer is crystalline and has a dielectric constant of at least 50.

18. The capacitor of claim 17 wherein at least a portion of the tantalum oxide layer is c-axis textured and has a hexagonal structure.

19. A semiconductor device comprising:
a semiconductor substrate or substrate assembly;
niobium nitride adjacent to at least a portion of the semiconductor substrate or substrate assembly;
a tantalum oxide layer adjacent to at least a portion of the niobium nitride; and
an electrode adjacent to at least a portion of the tantalum oxide layer.

20. The semiconductor device of claim 19 wherein the electrode comprises niobium nitride and/or ruthenium.

21. A method of forming a dielectric layer, comprising depositing a tantalum oxide layer adjacent to a surface comprising niobium nitride.

22. The method of claim 21 wherein the tantalum oxide layer is deposited using a vapor deposition method.

23. The method of claim 22 wherein the tantalum oxide is deposited at a deposition temperature of from 300° C. to 450° C.

24. The method of claim 22 wherein the vapor deposition method comprises chemical vapor deposition.

25. The method of claim 22 wherein the vapor deposition method comprises atomic layer deposition.

26. The method of claim 21 further comprising annealing the formed tantalum oxide layer.

27. A method of forming a dielectric layer, comprising:
providing an electrode comprising niobium nitride and having niobium oxide adjacent to at least a portion of a surface thereof; and
depositing a tantalum oxide layer adjacent to at least a portion of the surface of the electrode having niobium oxide thereon.

28. The method of claim 27 wherein at least a portion of the niobium oxide is amorphous, partially crystalline, or crystalline.

29. A method of making a capacitor, comprising:
forming a tantalum oxide layer adjacent to at least a portion of a first electrode comprising niobium nitride; and
forming a second electrode adjacent to at least a portion of the tantalum oxide layer.

30. A method of making a semiconductor device, comprising:
forming niobium nitride adjacent to at least a portion of a semiconductor substrate or substrate assembly;
forming a tantalum oxide layer adjacent to at least a portion of the niobium nitride; and
forming an electrode adjacent to at least a portion of the tantalum oxide layer.

31. The method of claim 30 wherein the niobium nitride is formed using a vapor deposition method.

32. The method of claim 31 wherein the vapor deposition method comprises chemical vapor deposition.

33. The method of claim 31 wherein the vapor deposition method comprises atomic layer deposition.

34. The method of claim 30 further comprising annealing the semiconductor device.

35. The method of claim 34 wherein the annealing comprises annealing before, during, and/or after forming the tantalum oxide layer.
